(19) United States
(12) Patent Application Publication
(10) Pub. No.: US 2018/0142341 A1
(43) Pub. Date: May 24, 2018

(54) VAPOR-DEPOSITION CRUCIBLE

(71) Applicants: BOE TECHNOLOGY GROUP CO., LTD., Beijing (CN); Ordos Yuansheng Optoelectronics Co., Ltd., Ordos ,Inner Mongolia (CN)

(72) Inventors: Lei CHEN, Beijing (CN); Xiaojin ZHANG, Beijing (CN)

(73) Assignees: BOE TECHNOLOGY GROUP CO., LTD., Beijing (CN); Ordos Yuansheng Optoelectronics Co., Ltd., Ordos ,Inner Mongolia (CN)

(21) Appl. No.: 15/030,593

(22) PCT Filed: Dec. 10, 2015
(86) PCT No.: PCT/CN2015/096940

§ 371 Date: Apr. 20, 2016

(30) Foreign Application Priority Data
May 15, 2015 (CN) 201510249701.3

(51) Int. Cl. C23C 14/24

(52) U.S. Cl. CPC C23C 14/243

(57) ABSTRACT

The present application discloses a vapor-deposition crucible comprising a crucible body for housing a vapor-deposition material and a heat conductor inside the crucible body. At least a portion of the heat conductor extends continuously from a region proximal to an interior surface of the crucible body to a region proximal to a center axis of the crucible body.

### CROSS-REFERENCE TO RELATED APPLICATION

This application claims priority to Chinese Patent Application No. 201510249701.3, filed May 15, 2015, the contents of which are incorporated by reference in the entirety.

### FIELD

The present invention relates to organic light emitting diode (OLED) manufacturing technology, more particularly, to a vapor-deposition crucible.

### BACKGROUND

In making an organic light emitting diode (OLED), the organic light emitting material is evaporated onto the base substrate using a vapor-deposition crucible. Specifically, the organic light emitting material is placed inside a crucible having heating filaments wrapped around its exterior surface. When power is applied to the heating filaments, the heating filaments heat the crucible, and the organic light emitting material evaporates or sublimes into a vapor. The evaporated or sublimed vapor then condenses when it reaches the base substrate on top of the crucible. The organic light emitting material is deposited on the base substrate.

### SUMMARY

In one aspect, the present invention provides a vapor-deposition crucible comprising a crucible body for housing a vapor-deposition material; and a heat conductor inside the crucible body.

Optionally, at least a portion of the heat conductor extends continuously from a region proximal to an interior surface of the crucible body to a region proximal to a center axis of the crucible body.

Optionally, the heat conductor is directly in contact with the interior surface of the crucible body.

Optionally, the heat conductor is in contact with the interior surface of the crucible body.

Optionally, the heat conductor extends continuously from a contact point with the interior surface of the crucible body to a region proximal to a center axis of the crucible body.

Optionally, two or more portions of the heat conductor are in contact with each other, the two or more portions jointly extend continuously from a contact point with the interior surface of the crucible body to a region proximal to the center axis of the crucible body.

Optionally, the heat conductor is a heating grate comprising a heat conductive body having a plurality of first through holes throughout the heat conductive body.

Optionally, the heating grate is substantially parallel to a bottom surface of the crucible body, a center axis of the heating grate substantially overlaps with a center axis of the crucible body at any point along the center axis of the heating grate.

Optionally, the heat conductive body has a higher distribution proportion in a region proximal to a center axis of the heating grate than in a region distal to the center axis of the heating grate.

Optionally, the plurality of first through holes have one or more shapes selected from a group consisting of square, rectangle, parallelogram, and triangle.

Optionally, the vapor-deposition crucible further comprises an anti-bumping metal plate having a plurality of second through holes, wherein the first through holes are larger in size than the second through holes.

Optionally, the vapor-deposition crucible comprises a plurality of heating grates spaced apart and substantially parallel to each other.

Optionally, the vapor-deposition crucible comprises two or three heating grates spaced apart and substantially parallel to each other.

Optionally, the vapor-deposition crucible further comprises a heat conductive frame, wherein the plurality of heating grates are secured to the heat conductive frame.

Optionally, the heating grate is a mesh.

Optionally, the heating grate is a plate having the plurality of first through holes.

Optionally, the heat conductor has a three-dimensional net structure.

Optionally, the heat conductor comprises a helix and a plurality of heat conductive bodies, the helix is in contact with an interior surface of the crucible body, and two ends of each of the plurality of heat conductive bodies are connected to the helix.

Optionally, the heat conductor comprises a first helix, a second helix, and a plurality of heat conductive bodies, the first helix and the second helix are in contact with an interior surface of the crucible body, each of the plurality of heat conductive bodies is substantially parallel to a bottom surface of the crucible body, two ends of each of the plurality of heat conductive bodies are connected to the first helix and the second helix, respectively.

Optionally, the heat conductor further comprises a heat conducting hollow column having an exterior contour substantially corresponding to an interior contour of the crucible body, other parts of the heat conductor are secured inside the heat conducting hollow column, and an exterior surface of the heat conducting column is in contact with the interior surface of the crucible body.

Optionally, the heat conductor is made of a material having high thermal conductivity, high thermal stability, and high corrosion resistivity.

Optionally, the heat conductor comprises a titanium alloy, molybdenum, or tungsten.

### BRIEF DESCRIPTION OF THE FIGURES

The following drawings are merely examples for illustrative purposes according to various disclosed embodiments and are not intended to limit the scope of the present invention.

FIG. 1 is a diagram illustrating the structure of a crucible in an embodiment.

FIG. 2 is a diagram illustrating the structure of a crucible during vapor deposition in another embodiment.

FIG. 3 is a diagram illustrating the structure of a heating grate in an embodiment.

FIG. 4 is a diagram illustrating the structure of a heating grate in another embodiment.

FIG. 5 is a diagram illustrating the structure of a heating grate in another embodiment.

FIG. 6 is a diagram illustrating the assembled structure of a heat conductive frame and a heating grate.

FIG. 7 is a diagram illustrating the assembled structure of a heat conducting hollow column and a heat conductor.

FIG. 8 is a diagram illustrating the structure of a crucible in another embodiment.

FIG. 9 is a diagram illustrating the structure of a crucible in another embodiment.

FIG. 10 is a diagram illustrating the structure of a heat conductor in another embodiment.

### DETAILED DESCRIPTION OF THE EMBODIMENTS

The disclosure will now describe more specifically with reference to the following embodiments. It is to be noted that the following descriptions of some embodiments are presented herein for purpose of illustration and description only. It is not intended to be exhaustive or to be limited to the precise form disclosed.

The organic light emitting material has a relatively low thermal conductivity. In conventional crucibles, the organic light emitting material in the core portion of the hollow crucible body has a lower temperature, and a higher temperature in the circumferential portion of the hollow crucible body. Consequently, the evaporation or sublimation rate of the organic light emitting material in the core portion is lower than that of the organic light emitting material in the circumferential portion. The different evaporation/sublimation rates result in caking of the organic material in the core portion, which leads to unstable vapor-deposition rate, lower utilization rate, and lower quality of the deposited layer. Because it takes longer time to vaporize the organic material in the core portion, the organic material may be partially converted into lower quality material or may be partially decomposed.

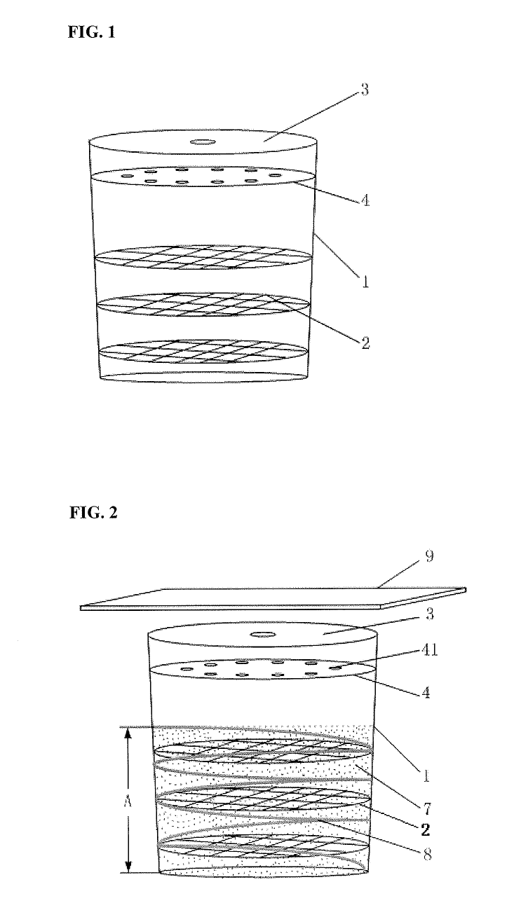

FIG. 1 is a diagram illustrating the structure of a crucible in an embodiment. FIG. 2 is a diagram illustrating the structure of a crucible during vapor deposition in another embodiment. Referring to FIGS. 1 and 2, the vapor-deposition crucible in the embodiments includes a crucible body 1(e.g., a hollow crucible body 1) and a heat conductor 2 disposed inside the crucible body 1. The crucible body 1 is to house a vapor-deposition material (e.g., an organic light emitting material 7 in FIG. 2). Optionally, the heat conductor 2 is to be in contact with the vapor-deposition material when housed inside the crucible body 1. The heat conductor 2 is configured to directly heat the vapor-deposition material to be housed inside the crucible body 1. Optionally, at least a portion of the heat conductor extends continuously from a region proximal to an interior surface of the crucible body to a region proximal to a center axis of the crucible body. The at least a portion can be one single portion that extends continuously from a region proximal to an interior surface of the crucible body to a region proximal to a center axis of the crucible body. Alternatively, the at least a portion can include two or more portions of the heat conductor in contact with each other. The two or more portions jointly extend continuously from a region proximal to an interior surface of the crucible body to a region proximal to a center axis of the crucible body. Optionally, the heat conductor extends continuously from a contact point with the interior surface of the crucible body to a region proximal to a center axis of the crucible body. Optionally, two or more portions of the heat conductor are in contact with each other, the two or more portions jointly extend continuously from a contact point with the interior surface of the crucible body to a region proximal to the center axis of the crucible body.

Referring to FIG. 2, the heating filaments 8 in the embodiment wrap around the exterior surface of the crucible body 1, forming a heating region A. Prior to vapor deposition, the heat conductor 2 is buried inside the organic material 7. An anti-bumping metal plate 4 is placed on top of the organic material 7. A crucible cover 3 is placed on top of the crucible body 1 to cover the crucible body 1. By heating the crucible body 1 around the heating region A, the organic light emitting material 7 is vapor deposited onto a substrate 9 on top of the crucible cover 3.

When power is applied to the heating filaments 8, the heating filaments 8 coverts electricity into heat, and heats the crucible body 1. Being highly thermal conductive, the crucible body 1 conducts heat from the heating filaments 8 to the interior of the crucible body 1, to the organic material 7 and the heat conductor 2. The organic material 7 housed proximal to the interior surface of the crucible body 1 evaporates or sublimes into a vapor. The organic material 7 housed distal to the interior surface of the crucible body 1 (e.g., in the core portion of a hollow crucible body 1) receives the heat transferred by the heat conductor 2 and evaporates or sublimes into a vapor. The evaporated or sublimed vapor travels through the through holes 41 of the anti-bumping metal plate 4, and exits the crucible body 1 from the through holes of the crucible cover 3. The vapor condenses into a thin film when it encounters the substrate 9 having a lower temperature on top of the crucible body 1. The condensed thin film forms the organic light emitting layer of an OLED.

Having thermally conductive heat conductor 2 inside the crucible body 1 has the advantage of direct heat transfer to the organic material 7 housed distal to the interior surface of the crucible body 1 (e.g., in the core portion of a hollow crucible body 1), as shown in FIG. 2. It minimizes the temperature and evaporation rate differences in the organic material 7 proximal to or distal to the interior surface of the crucible body 1, respectively (e.g., in the core portion or the circumferential portion of a hollow crucible body 1). It also prevents the agglomeration of the organic material 7 (e.g., caking) in the core portion of the crucible body 1. This promotes a uniform evaporation rate of the organic material 7 throughout the crucible body 1, and enhances the utilization efficiency of the organic material 7. Furthermore, the more uniform evaporation rate throughout the crucible body 1 leads to a more stable organic material 7 in the core portion of the crucible body 1, i.e., the properties of the organic material 7 in the core portion of the crucible body 1 can be maintained. These advantages result in superior organic thin film deposition results and superior OLED electrical and optical properties.

In some embodiments, the heat conductor 2 is in contact with the interior surface of the crucible body 1 or spaced apart from the interior surface by no more than a second predetermined distance. For example, the second predetermined distance can be 0.5 millimeter, and the heat conductor 2 is spaced apart from the interior surface of the crucible body 1 by no more than 0.5 millimeter. Optionally, the outer edge of the heat conductor 2 is in contact with the interior surface of the crucible body 1 or spaced apart from the interior surface by no more than a second predetermined distance. Optionally, every point along the outer edge of the heat conductor 2 is in contact with or spaced apart from the interior surface by no more than a second predetermined distance (e.g., 0.1 mm-0.5 mm, 0.5 mm-1 mm, 1 mm-2 mm, 2 mm-5 mm, no more than 5 mm, no more than 10 mm, no more than 20 mm, no more than 50 mm, no more than 100 mm).

In some embodiments, the heat conductor 2 is a heating grate having a heat conductive body 21 (FIGS. 3-5). The heat conductive body 21 has a plurality of first through holes 22 throughout its body. FIGS. 3-5 are diagrams illustrating the structures of heating grates in some embodiments. The heat conductors 2 in these embodiments transfer heat from the crucible body 1 through the heat conductive body 21 to the organic material 7 in the core portion of the crucible body 1. By having a plurality of through holes 22 throughout the heat conductive body 21, the evaporated organic material 7 is not obstructed by the heat conductor 2, and can easily travel through the heating region A during vapor deposition. It also make it easy to supplement the organic material 7 into the heating region A, e.g., the organic material 7 can be added into the heating region A through these through holes 22.

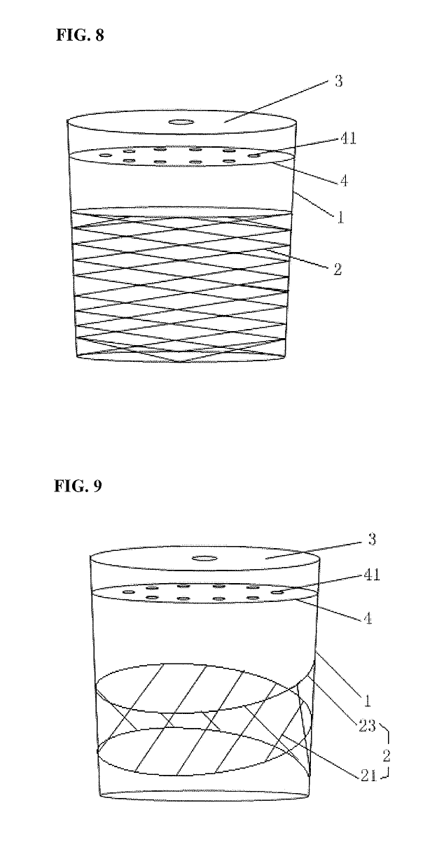

FIG. 8 is a diagram illustrating the structure of a crucible in another embodiment. Referring to FIG. 8, the heat conductor 2 in the embodiment has a three-dimensional net structure. The three-dimensional net structure can be optionally secured to the interior surface of the crucible body 1, and extends through the core portion of the crucible body 1. For example, the three-dimensional net can have a non-planar net structure, e.g., having straight or curved grid lines in different planes crossing each other and connected to form a regular or irregular three-dimensional net. For example, the non-planar net structure can be a net structure formed by twisting a planar net into a non-planar, three-dimensional structure. Optionally, the three-dimensional net structure is a helical net structure formed by twisting a planar net structure into a helix shape.

FIG. 9 is a diagram illustrating the structure of a crucible in another embodiment. Referring to FIG. 9, the heat conductor 2 in the embodiment includes a helix 23 and a plurality of heat conductive bodies 21. In the example, the helix 23 is disposed on the interior surface of the crucible body 1. Optionally, the helix 23 can be spaced apart from the interior surface of the crucible body 1 by a second predetermined distance. Each heat conductive body 21 has both ends connected to the helix 23, forming a three-dimensional net structure. Optionally, some heat conductive bodies 21 extend through the core portion of the crucible body 1. Optionally, some heat conductive bodies 21 are spaced apart from the center axis of the crucible body 1 by no more than a third predetermined distance. For example, the heat conductive body 21 closest to the center axis of the crucible body 1 is spaced apart from the center axis by no more than a third predetermined distance, e.g., no more than 0.5 millimeter.

In some embodiments, the helix 23 is in contact with the interior surface of the crucible body 1, and transfer heat from the crucible body 1 through the heat conductive body 21 to the organic material 7 in the core portion of the crucible body 1. The plurality of heat conductive bodies 21 are integrally formed, and can be conveniently taken out or disposed inside the crucible body 1. This type of heat conductor 2 facilitates cleaning of the crucible body 1.

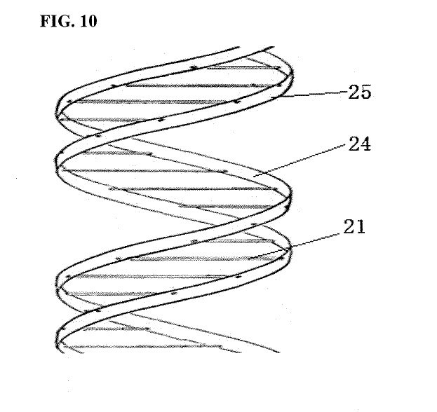

FIG. 10 is a diagram illustrating the structure of a heat conductor 2 in another embodiment. Referring to FIG. 10, the heat conductor 2 in the embodiment includes a first helix 24, a second helix 25, and a plurality of heat conductive bodies 21. In the example, the first helix 24 and the second helix 25 are in contact with the interior surface of the crucible body 1. Optionally, the first helix 24 and the second helix 25 are spaced apart from the interior surface of the crucible body 1 by a second predetermined distance. In the example, each of the plurality of heat conductive bodies 21 is substantially parallel to a bottom surface of the crucible. Each of the plurality of heat conductive bodies 21 has one end connected to the first helix 24 and the other to the second helix 25. Optionally, the first helix 24 and the second helix 25 are symmetrically disposed relative to the center axis of the crucible body 1.

In some embodiment, the heat conductor 2 has a double-helix structure (e.g., a double-helix structure similar to that of a DNA molecule). The first helix 24 and the second helix 25 form the backbone of the double helix, the plurality of the heat conductive bodies 21 form the “bridges” extending inward from the backbone and connecting two helices. In the example, the first helix 24 and the second helix 25 are in contact with the interior surface of the crucible body 1. Optionally, the first helix 24 and the second helix 25 are spaced apart from the interior surface of the crucible body 1 by a second predetermined distance. In the example, each of the plurality of heat conductive bodies 21 has one end connected to the first helix 24 and the other to the second helix 25. The helices 24 and 25 transfer heat from the crucible body 1 through the heat conductive bodies 21 to the organic material 7 housed in the core portion of the crucible body 1. The plurality of heat conductive bodies 21 are integrally formed, and can be conveniently taken out or disposed inside the crucible body 1. By having this type of heat conductor 2, the crucible body 1 can be easily cleaned.

In some embodiments, the first helix 24 and the second helix 25 start from two different points located on a circumference of a cross-section of the crucible body 1 substantially parallel to the bottom surface of the crucible body 1. Optionally, the two points is spaced apart by a distance, e.g., more than 1.5 times the radius of the cross-section. For example, the two points may be spaced apart by the diameter of the cross-section, i.e., the two points are symmetrically disposed relative to the center axis of the crucible body 1.

Referring to FIG. 1, the heating grate in the embodiment is substantially parallel to the bottom surface of the crucible body 1. The center axis of the heating grate substantially overlaps with, or are spaced apart by no more than a first predetermined distance from, the center axis of the crucible body 1 at any point along the center axis of the heating grate.

In some embodiments, the first predetermined distance is about 1 millimeter. For example, the center axis of the crucible body 1 extends through the heating grate at a point located within a circle having a radius of 1 millimeter around the center of the heating grate. Optionally, any point along the outer edge of the heating grate is spaced apart from the interior surface of the crucible body 1 by no more than the second predetermined distance (e.g., 0.5 millimeter). When the heating grate is substantially parallel to the bottom surface of the crucible body, the center axis of the heating grate substantially overlaps with, or is substantially parallel to, the center axis of the crucible body 1. When the center axis of the heating grate is substantially parallel to the center axis of the crucible body 1, the two center axes are spaced apart by no more than the first predetermined distance. When the heating grate is substantially parallel to the bottom surface of the crucible body 1, the two axes cross each other at an angle no more than a predetermined angle (e.g., 5 degrees). For example, the two axes can cross each other at an angle of about two degrees, about three degrees, or about 5 degrees. The heating filaments 8 wrap around the exterior surface of the crucible body 1. When the heating grate is substantially parallel to the bottom surface of the crucible body 1, heat can be evenly distributed throughout the organic material 7 along the direction from the exterior surface to the interior surface then to the core portion of the crucible body 1. This prevents bumping of the organic material 7 due to localized overheat, which leads to the clogging of the through holes 41 of the anti-bumping metal plate.

In some embodiments, the heat conductive body 21 has a higher distribution proportion in a region proximal to the center axis of the heating grate than a region distal to the center axis of the heating grate (FIGS. 3-5). The organic material 7 in the circumferential portion of the crucible body 1 is heated mainly by the interior surface, the organic material 7 in the core portion of the crucible body 1 is heated by the heat conductor 2. Typically, the organic material 7 itself has poor thermal conductivity. The heat transferred through the organic material 7 decreases significantly along the direction from the circumferential portion to the core portion of the crucible body 1. That is, the organic material 7 in the core portion of the crucible body 1 obtains much less heat as compared to the organic material 7 in the circumferential portion, if solely relying on heat exchange using the organic material 7 itself as the media.

The heat conductor 2, on the other hand, has excellent thermal conductivity. Heat is evenly distributed throughout the entire body of the heat conductive body 21. By having a higher distribution proportion of heat conductive bodies in a region proximal to the center axis of the heating grate, the contact surface between the organic material 7 and the heat conductive body 21 increases in the center region (core portion of the crucible body 1). That is, the organic material 7 in the core portion of the crucible body 1 can obtain more heat by heat exchange using the heat conductor 2 as the media. As a result, the entire body of organic material 7 can be evenly heated, preventing bumping due to localized overheat.

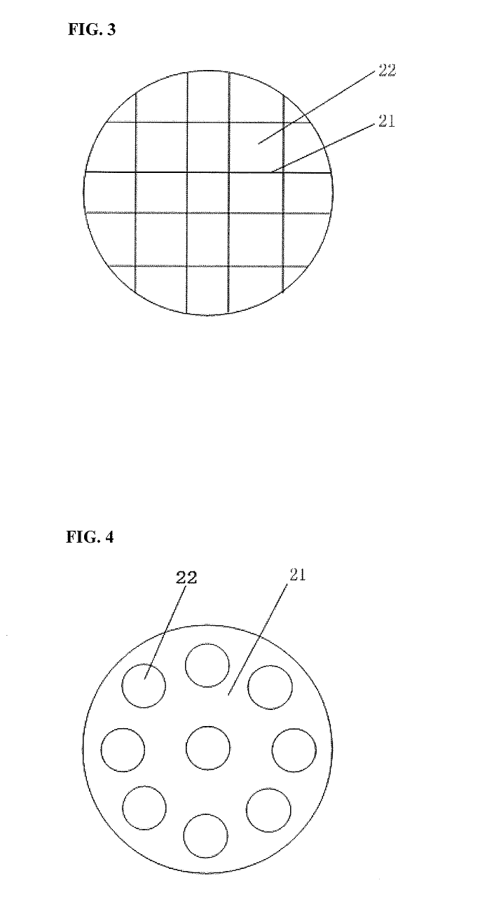

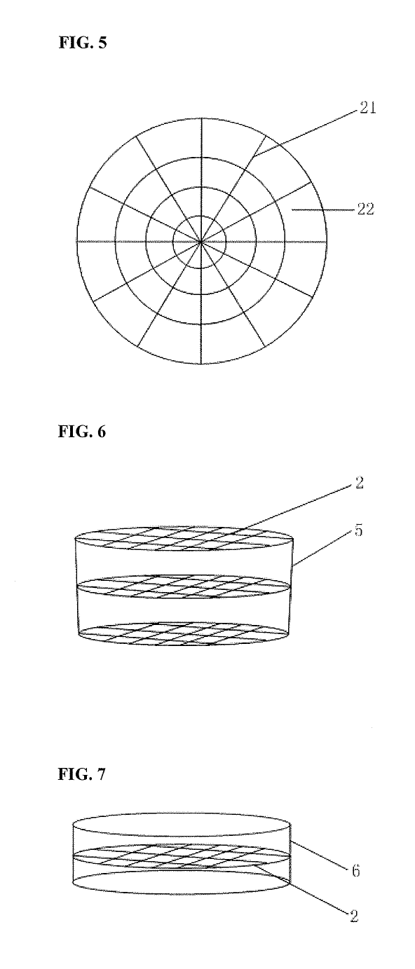

The first through holes 22 can have any suitable shape. In some embodiments, the plurality of first through holes 22 have one or more shapes selected from a group consisting of square, rectangle, parallelogram, and triangle (FIGS. 4 and 5).

In some embodiments, the crucible includes an anti-bumping metal plate 4 having a plurality of second through holes 41. In some embodiments, the first through holes 22 are larger than the second through holes 41 in size (FIGS. 1 and 2). This ensures a relatively high evaporation rate without affecting anti-bumping function of the crucible.

In some embodiments, the crucible includes a layered structure having a plurality of heating grates spaced apart and substantially parallel to each other (FIGS. 1, 2, and 6). Heat can be transferred from the crucible body 1 to the organic material 7 through a plurality of heating grates. By having a plurality of heating grates, heat can be distributed throughout the organic material 7 more evenly. For example, the entire core portion along the center axis of the crucible body 1 can be more evenly heated. This further prevents bumping of the organic material 7.

In some embodiments, the crucible includes a layered structure having two or three heating grates spaced apart and substantially parallel to each other (FIGS. 1 and 2). By limiting the number of layers to two or three, the evaporation rate and vapor deposition rate of the organic material 7 are not affected significantly, while still ensuring an even heat transfer throughout the organic material 7.

In some embodiments, the crucible includes a heat conductive frame 5 (FIG. 6). The heating grates are secured to the heating conductive frame 5. For example, a number of heat conductive bodies 21 can be integrally formed with the heat conductive frame 5 altogether. The integrally formed heat conductive bodies 21 can be conveniently taken out or disposed inside the crucible body 1. By having this type of heat conductor 2, the crucible body 1 can be easily installed or cleaned.

In some embodiments, the crucible body 1 has a larger cross-section on the top and a small cross-section in the bottom portion. For example, the radius of the cross-section of the crucible body 1 decreases from top to bottom. By having this design, the heat grates may be placed inside the crucible body 1 with or without a heat conductive frame 5. For example, the heat grates can have a series of different radii, each of which is larger than the radius of the bottom cross-section of the crucible body 1 but smaller than the radius of the top cross-section of the crucible body 1. The heat grates can be directly in contact with the interior surface of the crucible body 1. Optionally, when the organic material 7 is mainly vaporized by sublimation, the heat grates can be disposed proximal to, but not in contact with, the interior surface of the crucible body 1. For example, the heat grates can be disposed so that any point along the outer edge of the heat grates is within a second predetermined distance to the interior surface of the crucible body 1. In an exemplary vapor deposition process, a portion of the organic material 7 can be first placed inside the crucible body 1, followed by placing the heat grate on top of the portion of the organic material 7. The heat grate is then buried by another layer of the organic material 7 placed on top of the heat grate. Optionally, a second or more heat grates may be placed in the crucible body 1 in a similar fashion.

In some embodiments, the heating grate is a mesh (FIGS. 3 and 5). The heat is transferred from the interior surface of the crucible body 1 through the mesh to the organic material 7. By having a mesh type heat grate, the evaporated or sublimed organic material 7 can easily pass through the heating region A, thereby enhancing the vapor deposition rate of the organic material 7. The through hole 22 of the mesh can have any suitable shape, e.g., one or more shapes selected from a group consisting of square, rectangle, parallelogram, and triangle. In some embodiments, the heating grate is not a mesh but other types of heating grate.

In some embodiments, the heating grate is plate having the plurality of first through holes 22 (FIG. 4). The heat is transferred from the interior surface of the crucible body 1 through the plate to the organic material 7. By having a plate type heat grate, the heat transfer can be more efficient due to a larger contact area between the plate and the organic material 7. The through hole 22 of the plate heat grate can have any suitable shape, e.g., one or more shapes selected from a group consisting of square, rectangle, parallelogram, circle, eclipse, and triangle. In some embodiments, the heating grate is not a plate but other types of heating grate.

In some embodiments, the heat conductor further includes a heat conducting hollow column 6 having an exterior contour substantially corresponding to the interior contour of the crucible body (FIG. 7). The other parts of the heat conductor 2 (e.g., heat grates) is secured inside the heat conducting hollow column 6. In some embodiments, the exterior surface of the heat conducting column 6 is in contact with an interior surface of the crucible body 1. By having a heat conducting hollow column 6, the heat conductor 2 can have a larger contact surface area with the interior surface of the crucible body 1. This promotes efficient heat transfer from the crucible body 1 to the heat conductor 2.

In some embodiments, the heat conductor 2 comprises a plurality of heat grates disposed substantially parallel to each other. Optionally, the heat conducting hollow columns 6 and the plurality of heat grates can be integrally formed as a single body. This design facilitates efficient manufacturing, installation, and cleaning of the crucible.

The heat conductor 2 can be made of any suitable material. The temperature during the vapor deposition process is typically very high. Some organic materials 7 contain corrosive substances or may be decomposed to release corrosive substances. Therefore, the heat conductor 2 is optionally made of a material having high thermal conductivity, high thermal stability, and high corrosion resistivity. For example, the heat conductor 2 may be made of a titanium alloy, molybdenum, or tungsten. The heat conductor 2 can also be made of other suitable materials such as ceramics.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A vapor-deposition crucible, comprising:
a crucible body for housing a vapor-deposition material; and
a heat conductor inside the crucible body;
wherein at least a portion of the heat conductor extends continuously from a region proximal to an interior surface of the crucible body to a region proximal to a center axis of the crucible body.

2. The vapor-deposition crucible of claim 1, wherein the heat conductor is in contact with an interior surface of the crucible body.

3. The vapor-deposition crucible of claim 2, wherein the heat conductor extends continuously from a contact point with the interior surface of the crucible body to a region proximal to a center axis of the crucible body.

4. The vapor-deposition crucible of claim 3, wherein two or more portions of the heat conductor are in contact with each other, the two or more portions jointly extend continuously from a contact point with the interior surface of the crucible body to a region proximal to the center axis of the crucible body.

5. The vapor-deposition crucible of claim 1, wherein the heat conductor is a heating grate comprising a heat conductive body having a plurality of first through holes throughout the heat conductive body.

6. The vapor-deposition crucible of claim 5, wherein the heating grate is substantially parallel to a bottom surface of the crucible body, a center axis of the heating grate substantially overlaps with a center axis of the crucible body at any point along the center axis of the heating grate.

7. The vapor-deposition crucible of claim 5, wherein the heat conductive body has a higher distribution proportion in a region proximal to a center axis of the heating grate than in a region distal to the center axis of the heating grate.

8. The vapor-deposition crucible of claim 5, wherein the plurality of first through holes have one or more shapes selected from a group consisting of square, rectangle, parallelogram, and triangle.

9. The vapor-deposition crucible of claim 1, further comprising an anti-bumping metal plate having a plurality of second through holes, wherein the first through holes are larger in size than the second through holes.

10. The vapor-deposition crucible of claim 5, comprising a plurality of heating grates spaced apart and substantially parallel to each other.

11. The vapor-deposition crucible of claim 10, comprising two or three heating grates spaced apart and substantially parallel to each other.

12. The vapor-deposition crucible of claim 10, further comprising a heat conductive frame, wherein the plurality of heating grates are secured to the heat conductive frame.

13. The vapor-deposition crucible of claim 5, wherein the heating grate is a mesh.

14. The vapor-deposition crucible of claim 5, wherein the heating grate is a plate having the plurality of first through holes.

15. The vapor-deposition crucible of claim 1, wherein the heat conductor has a three-dimensional net structure.

16. The vapor-deposition crucible of claim 15, wherein the heat conductor comprises a helix and a plurality of heat conductive bodies, the helix is in contact with an interior surface of the crucible body, and two ends of each of the plurality of heat conductive bodies are connected to the helix.

17. The vapor-deposition crucible of claim 15, wherein the heat conductor comprises a first helix, a second helix, and a plurality of heat conductive bodies, the first helix and the second helix are in contact with an interior surface of the crucible body, each of the plurality of heat conductive bodies is substantially parallel to a bottom surface of the crucible body, and two ends of each of the plurality of heat conductive bodies are connected to the first helix and the second helix, respectively.

18. The vapor-deposition crucible of claim 1, wherein the heat conductor further comprises a heat conducting hollow column having an exterior contour substantially corresponding to an interior contour of the crucible body, other parts of the heat conductor are secured inside the heat conducting hollow column, and an exterior surface of the heat conducting column is in contact with the interior surface of the crucible body.

19. The vapor-deposition crucible of claim 1, the heat conductor is made of a material having high thermal conductivity, high thermal stability, and high corrosion resistivity.

20. The vapor-deposition crucible of claim 19, wherein the heat conductor comprises a titanium alloy, molybdenum, or tungsten.
